(19) United States
(12) Patent Application Publication
(10) Pub. No.: US 2019/0189699 A1
(43) Pub. Date: Jun. 20, 2019

(54) FLEXIBLE TOUCH PANEL AND OLED DISPLAY PANEL

(71) Applicant: WUHAN CHINA STAR OPTOELECTRONICS SEMICONDUCTOR DISPLAY TECHNOLOGY CO., LTD., Wuhan, Hubei (CN)

(72) Inventor: Jian YE, Wuhan, Hubei (CN)

(21) Appl. No.: 15/761,816

(22) PCT Filed: Jan. 4, 2018
(86) PCT No.: PCT/CN2018/071255

§ 371 Date: Mar. 21, 2018

(30) Foreign Application Priority Data
Dec. 14, 2017 (CN) 201711339603.4

(51) Int. Cl. H01L 27/32; H01L 51/52; G06F 3/044; G06F 3/041

(52) U.S. Cl. CPC H01L 27/323; H01L 51/5253; G06F 3/044; G06F 2203/04112; H01L 2251/5338; G06F 2203/04102; G06F 3/0412

(57) ABSTRACT

A flexible touch panel is provided, and includes a first conductive patters layer including a first driving electrode pattern and a first sensing electrode pattern; an insulating layer disposed on the first conductive pattern layer; and a second conductive pattern layer disposed on the insulating layer. The second conductive pattern layer includes a second driving electrode pattern and a second sensing electrode pattern. The first driving electrode pattern is electrically connected to the second driving electrode pattern. The first conductive electrode pattern is electrically connected to the second conductive electrode pattern.

### CROSS REFERENCE TO RELATED APPLICATIONS

This application is a U.S. National Phase application submitted under 35 U.S.C. § 371 of Patent Cooperation Treaty Application serial No. PCT/CN2018/071255, filed on Jan. 4, 2018, which claims the priority of China Patent Application serial No. 201711339603.4, filed on Dec. 14, 2017, the disclosures of which are incorporated herein by reference in their entirety.

### FIELD OF INVENTION

The present invention relates to the field of display technologies, and more particularly to a flexible touch panel and a flexible OLED display panel.

### BACKGROUND OF INVENTION

Organic light emitting diodes (OLED) possess many properties such as self-luminousity, fast response speeds, wide range of viewing angles, broad prospects for application, etc. Nowadays, flexible display panels are dominant.

As technologies of flexible OLED display panels are burgeoning, touch panels corresponding to the flexible OLED display panels are also required to possess flexible properties. Touch control wires of conventional touch panels are made of indium tin oxide (ITO) materials. However, ITO is a brittle metallic oxide material which is liable to fracture when bent and it is unable to meet flexible touch requirements.

Because metal meshes have fine flexibility, they are suitable for flexible touch screens. As shown in a conventional touch screen shown in FIGS. 1 and 2, the touch screen has to be manufactured individually and then attached on top of a display panel. A sensing layer of the touch screen including a conductive layer which is disposed on a surface of a substract 105, and the conductive layer includes a driving electrode 101 which is distributed in an array configuration. In general, the driving electrode 101 is directly connected with a sensing electrode 102 and is disconnected at an intersection of the sensing electrode 102 and the driving electrode 101, and then an insulating block 103 is partially positioned on the intersection of the electrode pattern, a conductive bridge 104 is then positioned on the insulating block 103 to connect the driving electrode 101 which is spaced at two sides of sensing electrodes 102. Or firstly, the conductive bridge 104 is manufactured, after that the insulating block 103 is manufactured, and finally, the driving electrode 101 and the sensing electrode 102 are manufactured.

For traditional touch screens which are based on metal meshes, area of the conductive material of the touch screen is about 5% to 10% of the shape and the area of the whole electrode. Therefore, contact areas of two ends of the conductive bridge are small, which are prone to high connection impedance or increase the risk of being open-circuited.

### SUMMARY OF INVENTION

The present disclosure provides a flexible touch panel, and the electrode can be connected independent to the traditional metal bridge frame with an extremely-small contact area in order to solve the technical problems that the contact areas between the two ends of the conductive bridge and the electrode are small, which prone to high connection impedance or increase the risk of being an open-circuit.

In order to solve the above problem, a technical scheme is provided by the disclosure is as follows:

The disclosure provides a flexible touch panel, comprising:

a flexible substrate;

a first conductive pattern layer disposed on the flexible substrate, wherein the first conductive pattern layer comprises at least two of first driving electrode patterns arranged in a first direction, and at least two of first sensing electrode patterns arranged in a second direction, and the first driving electrode pattern and the first sensing electrode pattern are crosswise-arranged; wherein each of the first driving electrode pattern in the first direction are connect end-to-end;

an insulating layer disposed on the first conductive pattern layer, wherein a surface of the insulating layer comprises a first area and a second area, a plurality of first metal through holes are defined in the first area, and a plurality of second metal through holes are defined in the second area; and

a second conductive pattern layer disposed on the insulating layer, wherein the second conductive pattern layer comprises at least two of second driving electrode patterns arranged in the first direction, and a second sensing electrode pattern arranged in the second direction, and the second driving electrode pattern and the second sensing electrode pattern are crosswise-arranged; wherein each of the second sensing electrode pattern in the second direction are connect end-to-end;

wherein a projection of the first driving electrode pattern projected on the insulating layer partially overlaps a projection of the second driving electrode pattern projected on the insulating layer, and the first driving electrode pattern is connected with the second driving electrode pattern via the first metal through hole;

wherein a projection of the first sensing electrode pattern projected on the insulating layer partially overlaps a projection of the second sensing electrode pattern projected on the insulating layer, and the first sensing electrode pattern is connected with the second sensing electrode pattern via the second metal through hole;

wherein each of the first driving electrode pattern, the second driving electrode pattern, the first sensing electrode pattern, and the second sensing electrode pattern comprises two rhombic metal meshes diagonally arranged;

wherein the first driving electrode pattern and the first sensing electrode pattern form a first rhombic electrode pattern; and

wherein the second driving electrode pattern and the second sensing electrode pattern form a second rhombic electrode pattern.

According to a preferred embodiment of the present disclosure, each of the first conductive pattern layer and the second conductive pattern layer is metal mesh layers, and display pixels are correspondingly positioned in meshes of the first conductive pattern layer and the second conductive pattern layer.

According to a preferred embodiment of the present disclosure, at least two of the first metal through holes are defined in the first area of the insulating layer, and at least two of the second metal through holes are defined in the second area of the insulating layer.

According to a preferred embodiment of the present disclosure, a shape and a size of the first area is equal to a shape and a size of the first driving electrode pattern, and equal to a shape and a size of the second driving electrode pattern; and a shape and a size of the second area is equal to a shape and a size of the first sensing electrode pattern, and equal to a shape and a size of the second sensing electrode pattern.

According to a preferred embodiment of the present disclosure, the flexible substrate is an encapsulation layer of a flexible organic fight-emitting diode (OLED) display panel.

The present disclosure also provides a flexible touch panel, comprising:

a flexible substrate;

a first conductive pattern layer is disposed on the flexible substrate, wherein the first conductive pattern layer comprises at least two of first driving electrode patterns arranged in a first direction, and at least two of first sensing electrode patterns arranged in a second direction, and the first driving electrode pattern and the first sensing electrode pattern are crosswise-arranged; wherein each of the first driving electrode pattern in the first direction are connect end-to-end;

an insulating layer is disposed on the first conductive pattern layer, wherein a surface of the insulating layer comprises a first area and a second area, a plurality of first metal through holes are defined in the first area, and a plurality of second metal through holes are defined in the second area; and

a second conductive pattern layer disposed on the insulating layer, wherein the second conductive pattern layer comprises at least two of second driving electrode patterns arranged in the first direction, and at least two of second sensing electrode patterns arranged in the second direction, and the second driving electrode pattern and the second sensing electrode pattern are crosswise-arranged; wherein each of the second sensing electrode pattern in the second direction are connect end-to-end;

wherein a projection of the first driving electrode pattern projected on the insulating layer partially overlaps a projection of the second driving electrode pattern projected on the insulating layer, and the first driving electrode pattern is connected with the second driving electrode pattern via the first metal through hole; and

wherein a projection of the first sensing electrode pattern projected on the insulating layer partially overlaps a projection of the second sensing electrode pattern projected on the insulating layer, and the first sensing electrode pattern is connected with the second sensing electrode pattern via the second metal through hole.

According to a preferred embodiment of the present disclosure, each of the first conductive pattern layer and the second conductive pattern layer is metal mesh layers, and the display pixels are correspondingly positioned in the meshes of the first conductive pattern layer and the second conductive pattern layer.

According to a preferred embodiment of the present disclosure, at least two of the first metal through holes are defined in the first area of the insulating layer; and at least two of the second metal through holes are defined in the second area of the insulating layer.

According to a preferred embodiment of the present disclosure, a shape and a size of the first area is equal to a shape and a size of the first driving electrode pattern, and equal to a shape and a size of the second driving electrode pattern; and a shape and a size of the second area is equal to a shape and a size of the first sensing electrode pattern, and equal to a shape and a size of the second sensing electrode pattern.

According to a preferred embodiment of the present disclosure, the flexible substrate is an encapsulation layer of a flexible organic light-emitting diode (OLED) display panel.

According to the above objects of the present disclosure, a flexible organic light-emitting diode (OILED) display panel is provided. The flexible organic light-emitting diode (OLED) display panel, comprising:

a flexible substrate;

an OLED display layer disposed on the flexible substrate;

an encapsulation layer formed on the flexible substrate and encapsulating the OLED display layer; and

a first conductive pattern layer disposed on the encapsulation layer, wherein the first conductive pattern layer comprises at least two of first driving electrode patterns arranged in a first direction and at least two of first sensing electrode patterns arranged in a second direction, and the first driving electrode pattern and the first sensing electrode pattern are crosswise-arranged;

an insulating layer disposed on the first conductive pattern layer, wherein a surface of the insulating layer comprises a first area and a second area, a plurality of first metal through holes are defined in the first area, and a plurality of second metal through holes are defined in the second area; and

a second conductive pattern layer disposed on the insulating layer, wherein the second conductive pattern layer comprises a second driving electrode pattern arranged in the first direction, and a second sensing electrode pattern arranged in the second direction, and the second driving electrode pattern and the second sensing electrode pattern are crosswise-arranged;

wherein a projection of the first driving electrode pattern projected on the insulating layer partially overlaps a projection of the second driving electrode pattern projected on the insulating layer, and the first driving electrode pattern is connected with the second driving electrode pattern via the first metal through hole;

wherein a projection of the first sensing electrode pattern projected on the insulating layer partially overlaps a projection of the second sensing electrode pattern projected on the insulating layer, and the first sensing electrode pattern is connected with the second sensing electrode pattern via the second metal through hole.

According to a preferred embodiment of the present disclosure, each of the first conductive pattern layer and the second conductive pattern layer is metal mesh layers, and display pixels are correspondingly positioned in meshes of the first conductive pattern layer and the second conductive pattern layer.

According to a preferred embodiment of the present disclosure, each of the first driving electrode pattern, the second driving electrode pattern, the first sensing electrode pattern, and the second sensing electrode pattern comprises two rhombic metal meshes diagonally arranged;

wherein the first driving electrode pattern and the first sensing electrode pattern form a first rhombic electrode pattern;

wherein the second driving electrode pattern and the second sensing electrode pattern form a second rhombic electrode pattern.

According to a preferred embodiment of the present disclosure, at least two of the first metal through holes are defined in the first area of the insulating layer, and at least two of the second metal through holes are defined in the second area of the insulating layer.

The beneficial effects of the present disclosure is that the flexible touch panel provided by the present disclosure, as compared with the prior art, disposed with two layers of touch control electrodes, and the two layers of touch control electrodes are correspondingly connected in order to replace the conduction design of the conductive bridge, and avoid the technical problems of high impedance and open-circuit caused by connection of the conductive bridges; The present disclosure solves the technical problems of the contact areas between the two ends of the conductive bridge and the electrode in the existing flexible touch panel are small that prone to high connection impedance or increase the risk of being an open-circuit.

### DESCRIPTION OF THE DRAWINGS

In order to illustrate a technical solution in the embodiments or in the prior art more clearly, the accompanying drawings required in the description of the embodiments or the prior art are introduced briefly hereafter. It is obvious that the accompanying drawings in the following description are merely part of the embodiments of the present invention. People with ordinary skills in the art can obtain other drawings without making inventive efforts.

FIG. 1 is a schematic structural view of electrodes of a touch panel in the prior art.

FIG. 2 is a schematic structural view of a touch panel film layer in the prior art.

FIG. 3 is an exploded structural view of a flexible touch panel of the present invention.

FIG. 4 is a schematic structural view of film layers of a flexible touch panel film layer of the present invention.

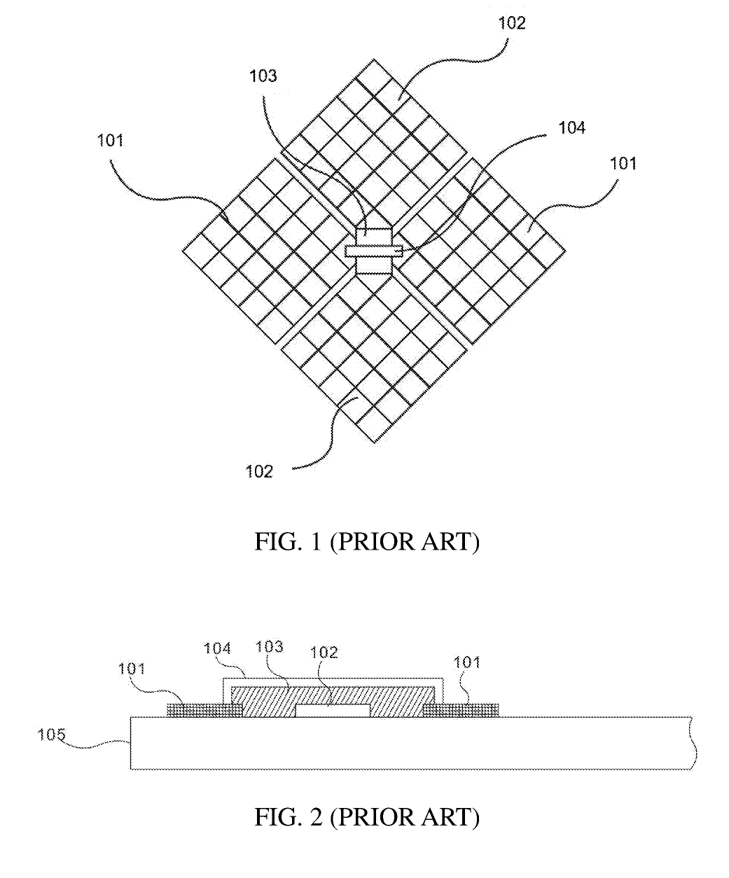

### DETAILED DESCRIPTION OF PREFERRED EMBODIMENTS

In the following detailed description, reference is made to the accompanying figures, in which various examples are shown by way of illustration. In this regard, directional terminology mentioned in the present disclosure, such as “top”, “bottom”, “front”, “back”, “left”, “right”, “inside”, “outside”, “lateral”, etc., is used with reference to the orientation of the figures being described. Therefore, the directional terminology is used for purposes of illustration and is not intended to limit the present invention. In the accompanying figures, units with similar structures are indicated by the same reference numbers.

The present disclosure defines the technical problems of the existing flexible touch panel that the contact areas between the two ends of the conductive bridge and the electrode are small and thus prone to high connection impedance or increase the risk of being an open-circuit. The present embodiment can solve that defect.

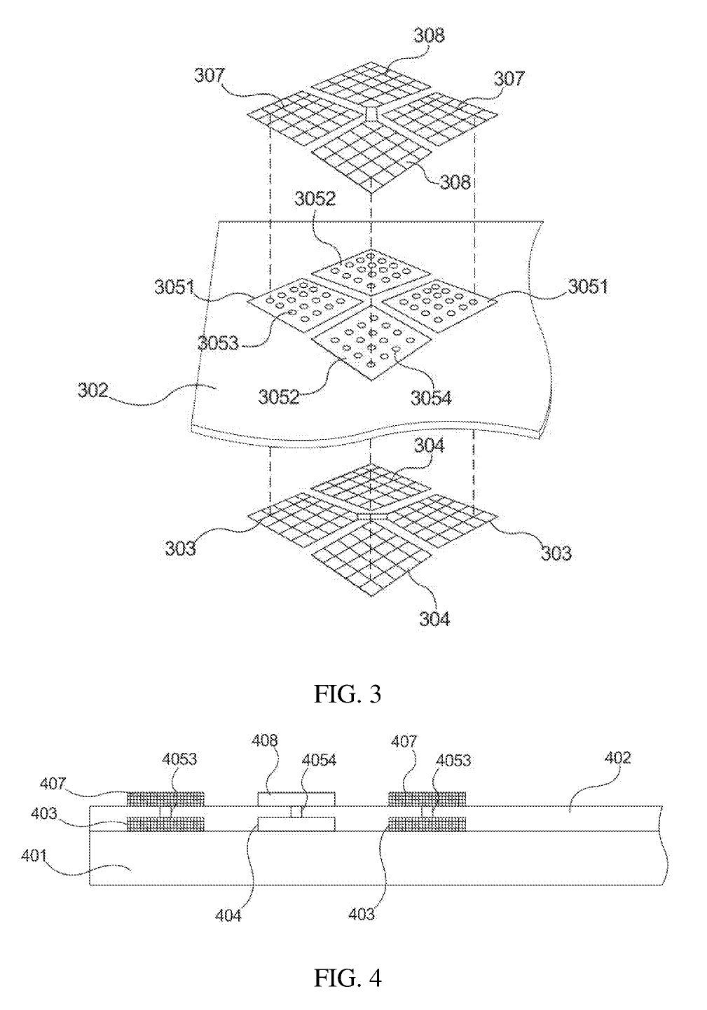

As shown in FIG. 3, the flexible touch panel provided by the present disclosure comprising: a flexible substrate 301, a first conductive pattern layer, an insulating layer 302, and a second conductive pattern layer.

The first conductive pattern layer is disposed on the flexible substrate 301. The first conductive pattern layer is disposed on the flexible substrate. The first conductive pattern layer comprises at least two of first driving electrode patterns 303 arranged in a first direction, and at least two of first sensing electrode patterns 304 arranged in a second direction. The first driving electrode pattern 303 and the first sensing electrode pattern 304 are crosswise-arranged, wherein each of the first driving electrode patterns 303 in the first direction are connected end-to-end, i.e. in the first direction, and the adjacent first driving electrode patterns 303 are electrically connected. The first sensing electrode patterns 304 in the second direction have no connection relationship. For example, if the first direction is transverse, and the second direction is vertical.

The insulating layer 302 is disposed on the first conductive pattern layer, a surface of the insulating layer 302 comprises a first area 3051 and a second area 3052, a plurality of first metal through holes 3053 are defined in the first area 3051, and a plurality of second metal through holes 3054 are defined in the second area 3052. Specifically, the first metal through hole and the second metal through hole are correspondingly distributed in a gap between two adjacent pixel units, so that the influence of the first metal through hole and the second metal through hole to screen display is avoided.

The first area 3051 corresponds to the first driving electrode pattern 303 and the second driving electrode pattern 307. The second area 3052 corresponds to the first sensing electrode pattern 304 and the second sensing electrode pattern 308.

The second conductive pattern layer is disposed on the insulating layer 302. The second conductive pattern layer comprises at least two of second driving electrode patterns 307 arranged in the first direction, and at least two of second sensing electrode patterns 308 arranged in the second direction The second driving electrode pattern 307 and the second sensing electrode pattern 308 are arranged are crosswise-arranged, wherein each of the second sensing electrode pattern 308 in the second direction are connect end-to-end, i.e. in the second direction, and the adjacent second sensing electrode patterns 308 are electrically connected. The second driving electrode patterns 307 in the first direction have no connection relationship.

A projection of the first driving electrode pattern 303 projected on the insulating layer 302 partially overlaps a projection of the second driving electrode pattern 307 projected on the insulating layer 302, and the first driving electrode pattern 303 is connected with the second driving electrode pattern 307 via the first metal through hole 3053.

A projection of the first sensing electrode pattern 304 projected on the insulating layer 302 partially overlaps a projection of the second sensing electrode pattern 308 projected on the insulating layer, and the first sensing electrode pattern 304 is connected with the second sensing electrode pattern 308 via the second metal through hole 3054.

By adding redundant electrode patterns and incorporate with achieving connections between driving electrodes and connections between sensing electrodes, the conductive bridges of the conventional touch panels for achieving connection between electrodes can be replaced.

Each of the first conductive pattern layer and the second conductive pattern layer is metal mesh layers. For example, the metal mesh layers can be made of metal material such as Ag, Ti, Al, or Mo.

A plurality of transverse metal wires and a plurality of longitudinal metal wires are perpendicularly crossed to form a metal mesh layer, and the display pixels are correspondingly positioned in the meshes of the first conductive pattern layer and the second conductive pattern layer to prevent the metal mesh block the display area, and affected the aperture ratios of the display pixels.

Each of the first driving electrode pattern 303, the second driving electrode pattern 307, the first sensing electrode pattern 304, and the second sensing electrode pattern 308 comprises two rhombic metal meshes diagonally arranged, wherein the first driving electrode pattern 303 and the first sensing electrode pattern 304 form a first rhombic electrode pattern, wherein the second driving electrode pattern 307 and the second sensing electrode pattern 308 form a second rhombic electrode pattern.

At least two of the first metal through holes 3053 are defined in the first area 3051 of the insulating layer 302, and at least two of the second metal through holes 3054 are defined in the second area 3052 of the insulating layer 302.

For example, the first metal through holes 3053 are 4×4, and the first metal through holes 3053 are distributed in an array configuration in the first area 3051, and each of the first metal through holes 3053 corresponds to an intersection point of any one of the transverse metal wires and the longitudinal metal wires. Similarly, the second metal through holes 3054 are 4×4, and the second metal through holes 3054 are distributed in an array configuration in the second area 3052, and each of the second metal through holes 3054 corresponds to an intersection point of any one of the transverse metal wires and the longitudinal metal wires.

A shape and a size of the first area 3051 is equal to a shape and a size of the first driving electrode pattern 303 and equal to a shape and a size of the second driving electrode pattern 307. A shape and a size of the second area 3052 is equal to shape and a size of the first sensing electrode pattern 304 and equal to a shape and a size of the second sensing electrode pattern 308.

The driving electrode pattern that is located at either end of the first driving electrode pattern 303 or the second driving electrode pattern 307 in the same row connects with a first connecting end of the driving signal line. The sensing electrode pattern that is located at either end of the first sensing electrode pattern 304 or the second sensing electrode pattern 308 in the same column connects with the sensing signal line of a first connecting end, the second connecting end of the driving signal line is connected with the corresponding pin of the touch control chip, the second connection end of the sensing signal line is connected with the corresponding pin of the touch control chip.

As shown in FIG. 4, the flexible touch panel provided by the present disclosure comprising: a flexible substrate 401, a first conductive pattern layer manufactured on the flexible substrate 401. The first conductive pattern layer comprises a first driving electrode pattern 403 and a first sensing electrode pattern 404An insulating layer 402 manufactured on the first conductive pattern layer. A first metal through hole 4053 and a second metal through hole 4054 defined in the insulating layer 402. A second conductive pattern layer manufactured on the insulating layer 402. The second conductive pattern layer comprises a second driving electrode pattern 407 and a second sensing electrode pattern 408.

The second driving electrode pattern 407 is connected with the first driving electrode pattern 403 via the first metal through hole 4053, the second sensing electrode pattern 408 is connected with the first sensing electrode pattern 404 via the second metal through hole 4054.

According to the above object of the present disclosure: a flexible substrate, an OLED display layer disposed on the flexible substrate, an encapsulation layer formed on the flexible substrate and encapsulating the OLED display layer A first conductive pattern layer disposed on the encapsulation layer, wherein the first conductive pattern layer comprises at least two first driving electrode patterns arranged in a first direction and at least two first sensing electrode patterns arranged in a second direction, and the first driving electrode pattern and the first sensing electrode pattern are crosswise-arranged An insulating layer disposed on the first conductive pattern layer, wherein a surface of the insulating layer comprises a first area and a second area, a plurality of first metal through holes are defined in the first area, and a plurality of second metal through holes are defined in the second area. A second conductive pattern layer disposed on the insulating layer, wherein the second conductive pattern layer comprises at least two second driving electrode patterns arranged in the first direction, and at least two second sensing electrode patterns arranged in the second direction, and the second driving electrode pattern and the second sensing electrode pattern are crosswise-arranged, wherein a projection of the first driving electrode pattern projected on the insulating layer partially overlaps a projection of the second driving electrode pattern projected on the insulating layer, and the first driving electrode pattern is connected with the second driving electrode pattern via the first metal through hole; wherein a projection of the first sensing electrode pattern projected on the insulating layer partially overlaps a projection of the second sensing electrode pattern projected on the insulating layer, and the first sensing electrode pattern is connected with the second sensing electrode pattern via the second metal through hole.

The working principle of the flexible OLED display panel of the present preferred embodiment is consistent with the working principle of the flexible touch panel of the above-mentioned preferred embodiment, reference can be made to the working principle of the flexible touch panel of the above-mentioned preferred embodiment for specific details, and will not go into details herein.

In summary, although the present invention has been described with preferred embodiments thereof, the above preferred embodiments is not used to limit the present invention. One of ordinarily skill in the art can carry out changes and modifications to the described embodiment without departing from the scope and the spirit of the invention that is intended to be limited only by the appended claims.

What is claimed is:

1. A flexible touch panel, comprising:
a flexible substrate;
a first conductive pattern layer disposed on the flexible substrate, wherein the first conductive pattern layer comprises a first driving electrode pattern arranged in a first direction, and a first sensing electrode pattern arranged in a second direction, and the first driving electrode pattern and the first sensing electrode pattern are crosswise-arranged;
an insulating layer disposed on the first conductive pattern layer, wherein a surface of the insulating layer comprises a first area and a second area, a plurality of first metal through holes are defined in the first area, and a plurality of second metal through holes are defined in the second area; and
a second conductive pattern layer disposed on the insulating layer, wherein the second conductive pattern layer comprises a second driving electrode pattern arranged in the first direction, and a second sensing electrode pattern arranged in the second direction, and the second driving electrode pattern and the second sensing electrode pattern are crosswise-arranged;
wherein a projection of the first driving electrode pattern projected on the insulating layer partially overlaps a projection of the second driving electrode pattern projected on the insulating layer, and the first driving electrode pattern is connected with the second driving electrode pattern via the first metal through hole;
wherein a projection of the first sensing electrode pattern projected on the insulating layer partially overlaps a projection of the second sensing electrode pattern projected on the insulating layer, and the first sensing electrode pattern is connected with the second sensing electrode pattern via the second metal through hole;
wherein each of the first driving electrode pattern, the second driving electrode pattern, the first sensing electrode pattern, and the second sensing electrode pattern comprises two rhombic metal meshes diagonally arranged;
wherein the first driving electrode pattern and the first sensing electrode pattern form a first rhombic electrode pattern; and
wherein the second driving electrode pattern and the second sensing electrode pattern form a second rhombic electrode pattern.

2. The flexible touch panel according to claim 1, wherein each of the first conductive pattern layer and the second conductive pattern layer is metal mesh layers, and display pixels are correspondingly positioned in meshes of the first conductive pattern layer and the second conductive pattern layer.

3. The flexible touch panel according to claim 1, wherein at least two of the first metal through holes are defined in the first area of the insulating layer, and at least two of the second metal through holes are defined in the second area of the insulating layer,

4. The flexible touch panel according to claim 3, wherein a shape and a size of the first area is equal to a shape and a size of the first driving electrode pattern, and equal to a shape and a size of the second driving electrode pattern; and
a shape and a size of the second area is equal to a shape and a size of the first sensing electrode pattern, and equal to a shape and a size of the second sensing electrode pattern.

5. The flexible touch panel according to claim 1, wherein the flexible substrate is an encapsulation layer of a flexible organic light-emitting diode (OLED) display panel.

6. A flexible touch panel, comprising:
a flexible substrate;
a first conductive pattern layer is disposed on the flexible substrate, wherein the first conductive pattern layer comprises a first driving electrode pattern arranged in a first direction, and a first sensing electrode pattern arranged in a second direction, and the first driving electrode pattern and the first sensing electrode pattern are crosswise-arranged;
an insulating layer is disposed on the first conductive pattern layer, wherein a surface of the insulating layer comprises a first area and a second area, a plurality of first metal through holes are defined in the first area, and a plurality of second metal through holes are defined in the second area; and
a second conductive pattern layer disposed on the insulating layer, wherein the second conductive pattern layer comprises a second driving electrode pattern arranged in the first direction, and a second sensing electrode pattern arranged in the second direction, and the second driving electrode pattern and the second sensing electrode pattern are crosswise-arranged;
wherein a projection of the first driving electrode pattern projected on the insulating layer partially overlaps a projection of the second driving electrode pattern projected on the insulating layer, and the first driving electrode pattern is connected with the second driving electrode pattern via the first metal through hole; and
wherein a projection of the first sensing electrode pattern projected on the insulating layer partially overlaps a projection of the second sensing electrode pattern projected on the insulating layer, and the first sensing electrode pattern is connected with the second sensing electrode pattern via the second metal through hole.

7. The flexible touch panel according to claim 6, wherein each of the first conductive pattern layer and the second conductive pattern layer is metal mesh layers, and the display pixels are correspondingly positioned in the meshes of the first conductive pattern layer and the second conductive pattern layer.

8. The flexible touch panel according to claim 6, wherein at least two of the first metal through holes are defined in the first area of the insulating layer; and at least two of the second metal through holes are defined in the second area of the insulating layer.

9. The flexible touch panel according to claim 8, wherein a shape and a size of the first area is equal to a shape and a size of the first driving electrode pattern, and equal to a shape and a size of the second driving electrode pattern; and
a shape and a size of the second area is equal to a shape and a size of the first sensing electrode pattern, and equal to a shape and a size of the second sensing electrode pattern.

10. The flexible touch panel according to claim 6, wherein the flexible substrate is an encapsulation layer of a flexible organic light-emitting diode (OLED) display panel.

11. A flexible organic light-emitting diode (OLED) display panel, comprising:
a flexible substrate;
an OLED display layer disposed on the flexible substrate;
an encapsulation layer formed on the flexible substrate and encapsulating the OLED display layer;
a first conductive pattern layer disposed on the encapsulation layer, wherein the first conductive pattern layer comprises a first driving electrode pattern arranged in a first direction and a first sensing electrode pattern arranged in a second direction, and the first driving electrode pattern and the first sensing electrode pattern are crosswise-arranged;
an insulating layer disposed on the first conductive pattern layer, wherein a surface of the insulating layer comprises a first area and a second area, a plurality of first metal through holes are defined in the first area, and a plurality of second metal through holes are defined in the second area; and
a second conductive pattern layer disposed on the insulating layer, wherein the second conductive pattern layer comprises a second driving electrode pattern arranged in the first direction, and a second sensing electrode pattern arranged in the second direction, and the second driving electrode pattern and the second sensing electrode pattern are crosswise-arranged;
wherein a projection of the first driving electrode pattern projected on the insulating layer partially overlaps a projection of the second driving electrode pattern projected on the insulating layer, and the first driving electrode pattern is connected with the second driving electrode pattern via the first metal through hole;
wherein a projection of the first sensing electrode pattern projected on the insulating layer partially overlaps a projection of the second sensing electrode pattern projected on the insulating layer, and the first sensing electrode pattern is connected with the second sensing electrode pattern via the second metal through hole.

12. The flexible OLED display panel according to claim 11, wherein each of the first conductive pattern layer and the second conductive pattern layer is metal mesh layers, and display pixels are correspondingly positioned in meshes of the first conductive pattern layer and the second conductive pattern layer.

13. The flexible OLED display panel according to claim 12, wherein each of the first driving electrode pattern, the second driving electrode pattern, the first sensing electrode pattern, and the second sensing electrode pattern comprises two rhombic metal meshes diagonally arranged;
wherein the first driving electrode pattern and the first sensing electrode pattern form a first rhombic electrode pattern;
wherein the second driving electrode pattern and the second sensing electrode pattern form a second rhombic electrode pattern.

14. The flexible OLED display panel according to claim 11, wherein at least two of the first metal through holes are defined in the first area of the insulating layer, and at least two of the second metal through holes are defined in the second area of the insulating layer.
